(19) United States
(12) Patent Application Publication
(10) Pub. No.: US 2023/0005993 A1
(43) Pub. Date: Jan. 5, 2023

(54) SOLID-STATE IMAGING ELEMENT

(71) Applicant: SONY SEMICONDUCTOR SOLUTIONS CORPORATION, Kanagawa (JP)

(72) Inventor: Nobuhiro KAWAI, Kanagawa (JP)

(21) Appl. No.: 17/778,233

(22) PCT Filed: Oct. 6, 2020
(86) PCT No.: PCT/JP2020/037797

§ 371 Date: May 19, 2022

(30) Foreign Application Priority Data
Nov. 20, 2019 (JP) 2019-209855

(51) Int. Cl. H01L 27/30; H04N 5/369; H04N 5/3745

(52) U.S. Cl. CPC H01L 27/307; H04N 5/379; H04N 5/3745

(57) ABSTRACT

A solid-state imaging element according to the present disclosure includes a photoelectric conversion layer, a first insulating layer (101), and a second insulating layer (102). The photoelectric conversion layer (photoelectric conversion film PD) includes an insulating film (GFa), a charge storage layer (203), and a photoelectric conversion film (PD) stacked between a first electrode (201) and a second electrode (202). The first insulating layer (101) is provided with gates of some pixel transistors in which the charge storage layer serves as a source, a drain, and a channel in a plurality of pixel transistors that processes signal charges photoelectrically converted by the photoelectric conversion film (PD). The second insulating layer (102) is provided with a pixel transistor other than the some pixel transistors in the plurality of pixel transistors.

### FIELD

The present disclosure relates to a solid-state imaging element.

### BACKGROUND

In recent years, as each imaging pixel of an image sensor, there is a solid-state imaging element in which three photoelectric conversion films for photoelectrically converting red light, green light, and blue light are stacked in three layers in a vertical direction to detect light of three colors by one unit pixel (for example, Patent Literature 1).

The solid-state imaging element includes a plurality of pixel transistors that processes signal charges photoelectrically converted by the photoelectric conversion films. For example, the solid-state imaging element includes pixel transistors such as a reset transistor that resets a signal charge, an amplification transistor that amplifies the signal charge, and a selection transistor that selects an imaging pixel from which the signal charge is read.

The pixel transistors such as the reset transistor, the amplification transistor, and the selection transistor are generally provided in the same layer.

### CITATION LIST

### Patent Literature

Patent Literature 1: JP 2005-51115 A

### SUMMARY

### Technical Problem

However, a solid-state imaging element in which all the pixel transistors are provided in the same layer has room for improvement from the viewpoint of performance.

Therefore, the present disclosure proposes a solid-state imaging element capable of improving performance by arrangement of the pixel transistors.

### Solution to Problem

A solid-state imaging element according to the present disclosure includes a photoelectric conversion layer, a first insulating layer, and a second insulating layer. The photoelectric conversion layer includes an insulating film, a charge storage layer, and a photoelectric conversion film stacked between a first electrode and a second electrode. The first insulating layer is provided with gates of some pixel transistors in which the charge storage layer serves as a source, a drain, and a channel in a plurality of pixel transistors that processes signal charges photoelectrically converted by the photoelectric conversion film. The second insulating layer is provided with a pixel transistor other than the some pixel transistors in the plurality of pixel transistors.

### BRIEF DESCRIPTION OF DRAWINGS

FIG. 1 is an explanatory diagram illustrating a planar configuration example of a solid-state imaging device according to the present disclosure.

FIG. 2 is an explanatory diagram illustrating an example of a cross-sectional structure of a solid-state imaging element according to the present disclosure.

FIG. 3 is an explanatory diagram illustrating a modified example of the cross-sectional structure of the solid-state imaging element according to the present disclosure.

FIG. 4 is an explanatory diagram illustrating another modified example of the cross-sectional structure of the solid-state imaging element according to the present disclosure.

FIG. 5 is an explanatory diagram illustrating another modified example of the cross-sectional structure of the solid-state imaging element according to the present disclosure.

FIG. 6 is an explanatory diagram illustrating another modified example of the cross-sectional structure of the solid-state imaging element according to the present disclosure.

FIG. 7 is an explanatory diagram illustrating another modified example of the cross-sectional structure of the solid-state imaging element according to the present disclosure.

FIG. 8 is an explanatory diagram illustrating another modified example of the cross-sectional structure of the solid-state imaging element according to the present disclosure.

FIG. 9 is an explanatory diagram illustrating another modified example of the cross-sectional structure of the solid-state imaging element according to the present disclosure.

FIG. 10 is an explanatory diagram illustrating another modified example of the cross-sectional structure of the solid-state imaging element according to the present disclosure.

FIG. 11A is an explanatory diagram of a multilayer wiring according to the present disclosure.

FIG. 11B is an explanatory diagram of the multilayer wiring according to the present disclosure.

FIG. 12 is a block diagram illustrating a configuration example of an embodiment of an imaging apparatus as an electronic apparatus to which the present disclosure is applied.

FIG. 13 is a diagram illustrating an example of a schematic configuration of an endoscopic surgery system.

FIG. 14 is a block diagram illustrating an example of functional configurations of a camera head and a CCU.

FIG. 15 is a block diagram illustrating an example of a schematic configuration of a vehicle control system.

FIG. 16 is an explanatory diagram illustrating an example of installation positions of a vehicle exterior information detection unit and an imaging unit.

### DESCRIPTION OF EMBODIMENTS

Hereinafter, embodiments of the present disclosure will be described with reference to the drawings. In each of the following embodiments, same parts are given the same reference signs to omit redundant description.

[1. Schematic Configuration of Solid-State Imaging Device]

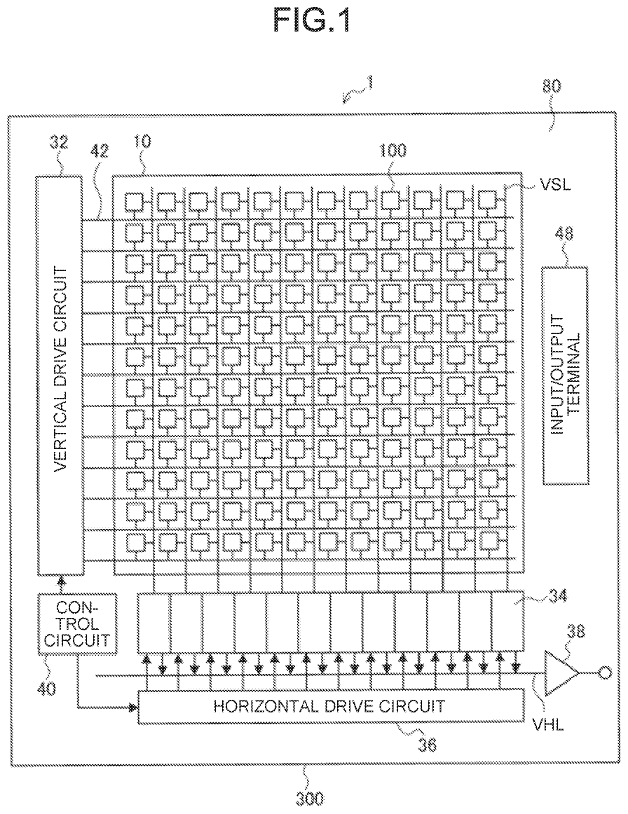

First, a planar configuration example of a solid-state imaging device according to the present disclosure will be described with reference to FIG. 1. FIG. 1 is an explanatory diagram illustrating the planar configuration example of the solid-state imaging device according to the present disclosure. As illustrated in FIG. 1, a solid-state imaging device 1 according to the present embodiment includes a pixel array unit 10 in which a plurality of pixels (solid-state imaging elements) 100 is arranged in a matrix on a semiconductor substrate 300 made of silicon, for example, and a peripheral circuit unit 80 provided so as to surround the pixel array unit 10.

The peripheral circuit unit 80 includes a vertical drive circuit 32, a column signal processing circuit 34, a horizontal drive circuit 36, an output circuit 38, a control circuit 40, and the like. Hereinafter, each block of the solid-state imaging device 1 according to the present embodiment will be described.

(Pixel Array Unit 10)

The pixel array unit 10 includes a plurality of solid-state imaging elements 100 two-dimensionally arranged in a matrix on the semiconductor substrate 300. Each of the plurality of solid-state imaging elements 100 includes a plurality of photoelectric conversion elements and a plurality of pixel transistors (e.g., metal oxide semiconductor (MOS) transistor). The plurality of pixel transistors includes, for example, a selection transistor, a reset transistor, and an amplification transistor.

(Vertical Drive Circuit 32)

The vertical drive circuit 32 is formed by, for example, a shift register. The vertical drive circuit 32 selects a pixel drive wiring 42, supplies a pulse for driving the solid-state imaging elements 100 to the selected pixel drive wiring 42, and drives the solid-state imaging elements 100 in units of rows. In other words, the vertical drive circuit 32 selectively scans each of the solid-state imaging elements 100 in the pixel array unit 10 in units of rows sequentially in the vertical direction (top-bottom direction in FIG. 1), and supplies a pixel signal based on a charge generated according to an amount of light received by the photoelectric conversion element of each of the solid-state imaging elements 100 to the column signal processing circuit 34 described later through a vertical signal line VSL.

(Column Signal Processing Circuit 34)

The column signal processing circuit 34 is arranged in each column of the solid-state imaging elements 100, and performs signal processing such as noise removal for each pixel column with respect to the pixel signals output from the solid-state imaging elements 100 for one row. For example, the column signal processing circuit 34 performs signal processing such as correlated double sampling (CDS) and analog to digital (AD) conversion in order to remove pixel-specific fixed pattern noise.

(Horizontal Drive Circuit 36)

The horizontal drive circuit 36 is formed of, for example, a shift register, and can sequentially select each of the column signal processing circuits 34 described above by sequentially outputting horizontal scanning pulses, and can cause each of the column signal processing circuits 34 to output a pixel signal to a horizontal signal line VHL.

(Output Circuit 38)

The Output Circuit 38 can Perform Signal Processing on the pixel signals sequentially supplied from each of the column signal processing circuits 34 described above through the horizontal signal line VHL, and output processed signals. The output circuit 38 may function as, for example, a functional unit that performs buffering, or may perform processing such as black level adjustment, column variation correction, and various digital signal processes. Note that buffering refers to temporarily storing pixel signals in order to compensate for differences in processing speed and transfer speed when the pixel signals are exchanged. An input/output terminal 48 is a terminal for exchanging signals with an external device.

(Control Circuit 40)

The control circuit 40 can receive an input clock and data instructing an operation mode and the like, and can output data such as internal information of the solid-state imaging element 100. In other words, the control circuit 40 generates, according to the vertical synchronization signal, the horizontal synchronization signal, and the master clock, a clock signal or a control signal serving as a reference for operations of the vertical drive circuit 32, the column signal processing circuit 34, the horizontal drive circuit 36, and the like. Then, the control circuit 40 outputs the generated clock signal and control signal to the vertical drive circuit 32, the column signal processing circuit 34, the horizontal drive circuit 36, and the like.

Note that the planar configuration example of the solid-state imaging device 1 according to the present embodiment is not limited to the example illustrated in FIG. 1, and may include, for example, other circuits, and is not particularly limited thereto.

[2. Cross-Sectional Structure of Solid-State Imaging Element]

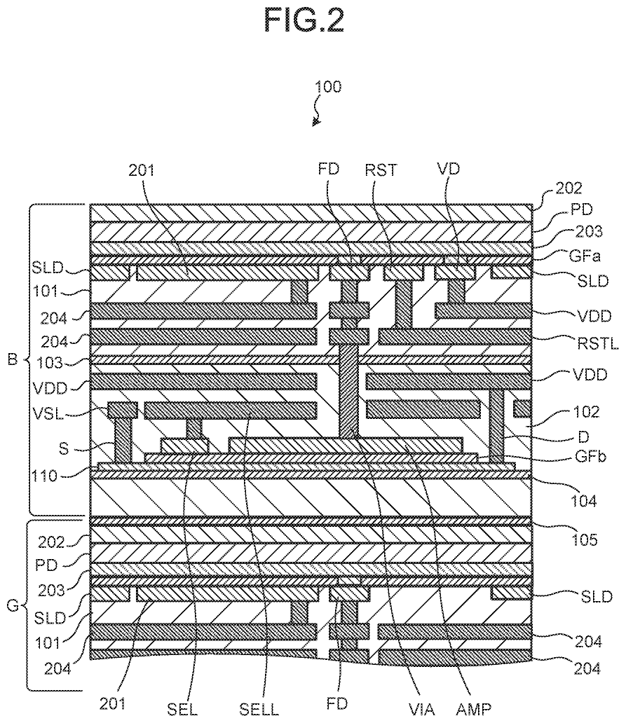

Next, an example of a cross-sectional structure of the solid-state imaging element according to the present disclosure will be described with reference to FIG. 2. FIG. 2 is an explanatory diagram illustrating the example of the cross-sectional structure of the solid-state imaging element according to the present disclosure. Here, a description will be given assuming that light enters from an uppermost layer side of a stacked structure illustrated in FIG. 2. Note that, in FIG. 2, illustration of a microlens provided on the uppermost layer of the solid-state imaging element 100 and a sealing layer provided below the microlens are omitted.

As illustrated in FIG. 2, the solid-state imaging element 100 includes a light receiving unit B that detects blue light on an upper layer side from which light enters. Furthermore, the solid-state imaging element 100 includes a light receiving unit G that detects green light below the light receiving unit B that detects blue light. Note that FIG. 2 illustrates a part of the light receiving unit G that detects green light.

Furthermore, the solid-state imaging element 100 includes a light receiving unit (not illustrated) that detects red light below the light receiving unit G that receives green light. As a result, the solid-state imaging element 100 can detect the light of three colors by one imaging pixel.

Assuming that the light receiving unit B that detects blue light, the light receiving unit G that detects green light, and the light receiving unit that detects red light have the same structure, the structure of the light receiving unit B that detects blue light will be described below. The components of the light receiving unit G that detects green light in the drawing are given the same reference signs as those of the light receiving unit B that detects blue light, and redundant description of the light receiving unit that detects red light is omitted.

The light receiving unit B includes a photoelectric conversion layer on a light incident side, and the photoelectric conversion layer photoelectrically converts incident light into a signal charge. The photoelectric conversion layer includes a gate insulating film GFa, a charge storage layer 203, and a photoelectric conversion film PD stacked between a first electrode 201 serving as a lower electrode and a second electrode 202 serving as an upper electrode.

The first electrode 201 and the second electrode 202 are formed of, for example, a transparent conductive film such as indium tin oxide (ITO). The gate insulating film GFa is formed of, for example, silicon oxide (SiO) or the like. The charge storage layer 203 is formed of, for example, a transparent oxide semiconductor. The photoelectric conversion film PD is formed of an organic film having optical wavelength selectivity.

The photoelectric conversion film PD photoelectrically converts incident light having a predetermined wavelength (here, blue light) into the signal charge. The first electrode 201 is connected to a charge storage wiring 204. The solid-state imaging element 100 applies a predetermined voltage between the first electrode 201 and the second electrode 202, thereby storing signal charges in a region between the first electrode 201 and the second electrode 202 in the charge storage layer 203.

Furthermore, the solid-state imaging element 100 includes a first insulating layer 101 below the photoelectric conversion layer. The first insulating layer 101 is formed of, for example, tetraethoxysilane (TEOS) or the like. The first electrode 201 is provided on an uppermost layer of the first insulating layer 101.

In addition, a gate of the reset transistor (hereinafter referred to as a reset gate RST) is provided in the same layer (uppermost layer) as the layer on which the first electrode 201 is provided in the first insulating layer 101. The reset gate RST is connected to a reset line RSTL. In the uppermost layer of the first insulating layer 101, a transfer electrode FD serving as a source electrode of the reset transistor and a discharge electrode VD serving as a drain electrode of the reset transistor are provided.

Furthermore, a shield SLD that electrically isolates the solid-state imaging elements 100 from each other is provided on the uppermost layer of the first insulating layer 101. The reset gate RST, the transfer electrode FD, the discharge electrode VD, and the shield SLD are formed of a transparent conductive film.

The transfer electrode FD is connected to a gate of the amplification transistor described later (hereinafter referred to as an amplification gate AMP) via a through electrode VIA. The discharge electrode VD is connected to a power supply line VDD. Each of these electrodes and signal lines is formed of a transparent conductive film. Note that signal lines that are particularly desired to have low resistance, such as the power supply line VDD and the vertical signal line VSL, may be formed of metal wiring instead of the transparent conductive film.

In the reset transistor, a region facing the reset gate RST via the gate insulating film GFa in the charge storage layer 203 serves as a channel, a region facing the transfer electrode FD in the charge storage layer 203 serves as a source, and a region facing the discharge electrode VD in the charge storage layer 203 serves as a drain.

When a predetermined voltage is applied to the reset gate RST before the signal charge stored in the charge storage layer 203 on the first electrode 201 are transferred to the charge storage layer 203 on the transfer electrode FD, the reset transistor discharges unnecessary charge existing in the charge storage layer 203 on the transfer electrode FD to the power supply line VDD to reset the charge storage layer 203.

As described above, among the plurality of pixel transistors that processes the signal charges photoelectrically converted by the photoelectric conversion film PD, the first insulating layer 101 is provided with the reset gate RST of the reset transistor in which the charge storage layer 203 serves as the source, the drain, and the channel.

Furthermore, the solid-state imaging element 100 includes a second insulating layer 102 below the first insulating layer 101 via an insulating film 103. The insulating film 103 is formed of, for example, SiO or the like. The second insulating layer 102 is formed of, for example, TEOS or the like. Note that an insulating film 105 is provided between the second insulating layer 102 and the light receiving unit G that detects green light. The insulating film 105 is formed of, for example, SiO or the like.

Among the plurality of pixel transistors, the second insulating layer 102 is provided with the amplification transistor and the selection transistor that are pixel transistors other than the reset transistor. In the second insulating layer 102, an intermediate insulating film 104 is provided between the insulating film 105 provided in the lowermost layer and the insulating film 103 provided in the uppermost layer, and the amplification transistor and the selection transistor are provided on the intermediate insulating film 104.

Specifically, a transparent semiconductor layer 110 is provided on the intermediate insulating film 104, and the amplification gate AMP and a gate of the selection transistor (hereinafter referred to as a selection gate SEL) are provided on one main surface (here, upper surface) of the transparent semiconductor layer 110 via a gate insulating film GFb. The amplification gate AMP and the selection gate SEL are formed of, for example, a transparent conductive film. The intermediate insulating film 104 and the gate insulating film GFb are made of, for example, SiO.

Further, a source electrode S and a drain electrode D are provided on both sides interposing the amplification gate AMP and the selection gate SEL on one main surface (here, upper surface) of the transparent semiconductor layer 110. The amplification gate AMP is connected to the transfer electrode FD via the through electrode VIA. The selection gate SEL is connected to a selection signal line SELL.

The source electrode S is connected to the vertical signal line VSL. The drain electrode D is connected to the power supply line VDD. The source electrode S and the drain electrode D are formed of, for example, a transparent conductive film. The source electrode S and the drain electrode D are shared by the amplification transistor and the selection transistor.

The gate insulating film GFb is shared by the amplification transistor and the selection transistor. In addition, the transparent semiconductor layer 110 serves as a channel, a source, and a drain shared by the amplification transistor and the selection transistor.

Specifically, in a case where the solid-state imaging element 100 is selected as a pixel from which the signal charge is read, a predetermined voltage is applied to the selection gate SEL, and the selection transistor is turned on. At this point, in a state that the charge storage layer 203 is not reset, a voltage corresponding to the signal charge stored in the charge storage layer 203 is applied to the amplification gate AMP and the amplification transistor is turned on in the solid-state imaging element 100.

As a result, the solid-state imaging element 100 outputs a pixel signal of a voltage corresponding to the photoelectrically converted signal charge from the power supply line VDD to the vertical signal line VSL via the drain electrode D, the transparent semiconductor layer 110, and the source electrode S.

As described above, in the solid-state imaging element 100, the reset gate RST of the reset transistor among the plurality of pixel transistors is provided in the first insulating layer 101. Then, among the plurality of pixel transistors other than the reset transistor, the second insulating layer 102 is provided with the amplification transistor and the selection transistor in the solid-state imaging element 100.

As a result, for example, the solid-state imaging element 100 can increase an area of the first electrode 201 as compared with a case where all the gates of the reset transistor, the amplification transistor, and the selection transistor are provided in the first insulating layer 101. Accordingly, the solid-state imaging element 100 can improve a light receiving sensitivity by increasing the number of saturated electrons in the charge storage layer 203.

Furthermore, the solid-state imaging element 100 can expand an area of the amplification gate AMP as compared with the case where all of the reset transistor, the amplification transistor, and the selection transistor are provided in the second insulating layer 102. Accordingly, the solid-state imaging element 100 can reduce noise superimposed on the pixel signal and increase an operation speed of the amplification transistor by expanding the channel of the amplification transistor.

Furthermore, as illustrated in FIG. 2, in the solid-state imaging element 100, the amplification gate AMP is provided so as to partially overlap the first electrode 201 in the vertical direction in a plan view. As a result, the amplification gate AMP and the first electrode 201 can be expanded in area without being restricted by their areas in a plane direction.

Accordingly, in the solid-state imaging element 100, the light receiving sensitivity is improved by expanding the area of the first electrode 201 to increase the number of saturated electrons in the charge storage layer 203, and the area of the amplification gate AMP is expanded to further reduce noise and increase the operation speed of the amplification transistor.

[3. Modified Examples of Cross-Sectional Structure of Solid-State Imaging Element]

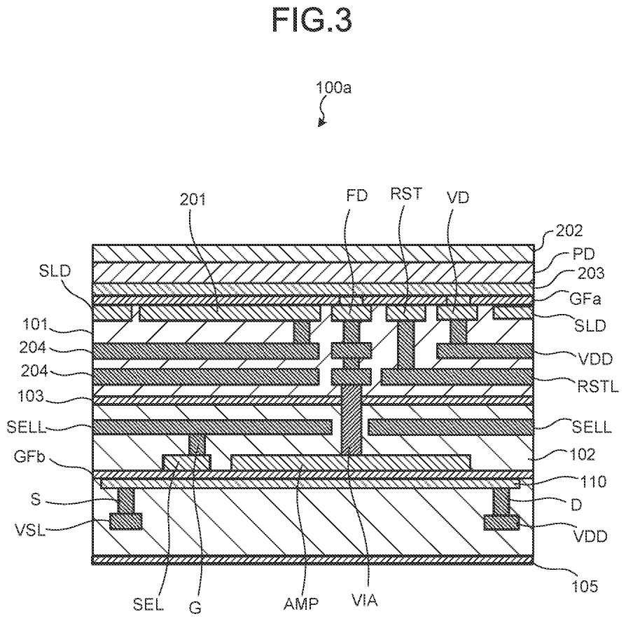

The cross-sectional structure of the solid-state imaging element illustrated in FIG. 2 is an example, and various modifications are possible. Next, modified examples of the cross-sectional structure of the solid-state imaging element according to the present disclosure will be described with reference to FIG. 3 to FIG. 9. FIG. 3 to FIG. 9 are explanatory diagrams illustrating modified examples of the cross-sectional structure of the solid-state imaging element according to the present disclosure.

FIG. 3 to FIG. 9 selectively illustrate the light receiving unit B that detects blue light in the solid-state imaging element according to each of the modified examples. Note that, in the following description of the modified examples, components in FIG. 3 to FIG. 9 having functions similar to those of the components illustrated in FIG. 2 are given the same reference signs as those illustrated in FIG. 2 to omit redundant description.

### First Modified Example

As illustrated in FIG. 3, in a solid-state imaging element 100a according to a first modified example, an internal structure of the second insulating layer 102 is different from that of the solid-state imaging element 100 illustrated in FIG. 2, and the structure above the second insulating layer 102 is the same as that of the solid-state imaging element 100 illustrated in FIG. 2.

Therefore, the internal structure of the second insulating layer 102 in the solid-state imaging element 100a will be described below. As illustrated in FIG. 3, in the solid-state imaging element 100a, the amplification gate AMP and the selection gate SEL are provided on one main surface (here, upper surface) of the transparent semiconductor layer 110 provided in the second insulating layer 102 via the gate insulating film GFb. The solid-state imaging element 100a includes the source electrode S and the drain electrode connected to the other main surface (here, lower surface) of the transparent semiconductor layer 110.

As described above, in the solid-state imaging element 100a, similarly to the solid-state imaging element 100 illustrated in FIG. 2, the reset gate RST is provided in the first insulating layer 101, and the amplification transistor and the selection transistor are provided in the second insulating layer 102.

As a result, the solid-state imaging element 100a can improve the light receiving sensitivity by increasing the area of the first electrode 201 as compared with the case where all the gates of the reset transistor, the amplification transistor, and the selection transistor are provided in the first insulating layer 101.

Still more, in the solid-state imaging element 100a, noise can be reduced and the speed can be increased by enlarging the area of the amplification gate AMP as compared with a case where all of the reset transistor, the amplification transistor, and the selection transistor are provided in the second insulating layer.

Furthermore, in the solid-state imaging element 100a, the amplification gate AMP and the through electrode VIA are connected, and the selection gate SEL and the selection signal line SELL are connected on one main surface side of the transparent semiconductor layer 110, which means above the transparent semiconductor layer 110.

Furthermore, in the solid-state imaging element 100a, the source electrode S and the vertical signal line VSL are connected, and the drain electrode D and the power supply line VDD are connected on the other main surface side of the transparent semiconductor layer 110, which means below the transparent semiconductor layer 110.

As a result, in the solid-state imaging element 100a, since a routing flexibility of the selection signal line SELL, the vertical signal line VSL, and the power supply line VDD in the second insulating layer 102 is improved, it is possible to provide appropriate wiring route in consideration of translucency.

### Second Modified Example

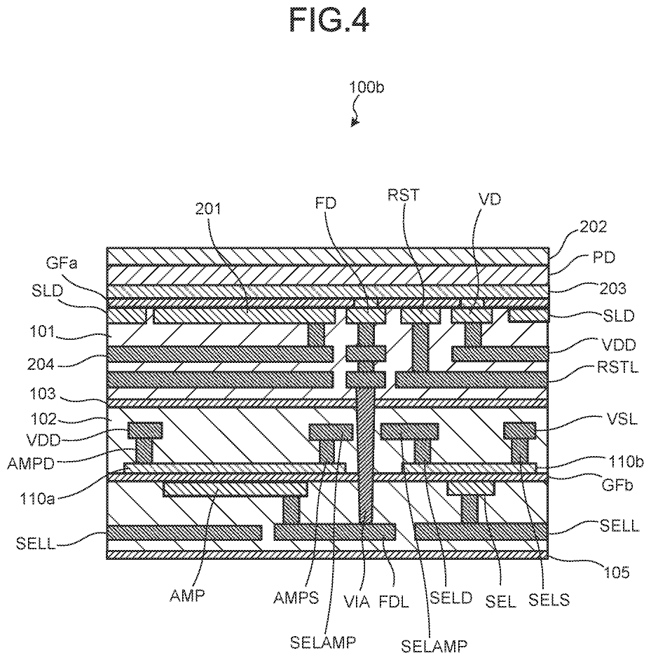

As illustrated in FIG. 4, in a solid-state imaging element 100b according to a second modified example, the internal structure of the second insulating layer 102 is different from that of the solid-state imaging element 100 illustrated in FIG. 2, and the structure above the second insulating layer 102 is the same as that of the solid-state imaging element 100 illustrated in FIG. 2.

As illustrated in FIG. 4, the internal structure of the second insulating layer 102 in the solid-state imaging element 100b is substantially similar to a structure obtained by inverting the top and bottom of the internal structure of the second insulating layer 102 illustrated in FIG. 3. Specifically, in the solid-state imaging element 100b, the amplification gate AMP is provided on one main surface (here, lower surface) of a transparent semiconductor layer 110a via the gate insulating film GFb, and the other main surface (here, upper surface) of the transparent semiconductor layer 110a faces the first insulating layer 101. A source electrode AMPS and a drain electrode AMPD of the amplification transistor are connected to the other main surface (here, upper surface) of the transparent semiconductor layer 110a.

Furthermore, in the solid-state imaging element 100b, the selection gate SEL is provided on the one main surface (here, lower surface) of a transparent semiconductor layer 110b via the gate insulating film GFb, and the other main surface (here, upper surface) of the transparent semiconductor layer 110b faces the first insulating layer 101. A source electrode SELS and a drain electrode SELD of the selection transistor are connected to the other main surface (here, upper surface) of the transparent semiconductor layer 110b.

In the solid-state imaging element 100b, the source electrode AMPS of the amplification transistor and the drain electrode SELD of the selection transistor are connected by a connection wiring SELAMP. In addition, the through electrode VIA and the amplification gate AMP are connected by a connection wiring FDL. The connection wirings SELAMP and FDL are formed of a transparent conductive film.

As described above, in the solid-state imaging element 100b, similarly to the solid-state imaging element 100 illustrated in FIG. 2, the reset gate RST is provided in the first insulating layer 101, and the amplification transistor and the selection transistor are provided in the second insulating layer 102.

As a result, the solid-state imaging element 100b can improve the light receiving sensitivity by increasing the area of the first electrode 201 as compared with the case where all the gates of the reset transistor, the amplification transistor, and the selection transistor are provided in the first insulating layer 101.

Still more, in the solid-state imaging element 100b, noise can be reduced and the speed can be increased by enlarging the area of the amplification gate AMP as compared with the case where all of the reset transistor, the amplification transistor, and the selection transistor are provided in the second insulating layer.

Furthermore, in the solid-state imaging element 100b, the amplification gate AMP and the through electrode VIA are connected, and the selection gate SEL and the selection signal line SELL are connected on one main surface side of the transparent semiconductor layers 110a and 110b, which means below the transparent semiconductor layers 110a and 110b.

Furthermore, in the solid-state imaging element 100b, the source electrode SELS of the selection transistor and the vertical signal line VSL are connected, and the drain electrode AMPD of the amplification transistor and the power supply line VDD are connected on the other main surface side of the transparent semiconductor layers 110a and 110b, which means above the transparent semiconductor layers 110a and 110b.

As a result, in the solid-state imaging element 100a, since a routing flexibility of the selection signal line SELL, the vertical signal line VSL, and the power supply line VDD in the second insulating layer 102 is improved, it is possible to provide appropriate wiring route in consideration of translucency. Similarly, the connection wirings SELAMP and FDL can also be appropriately routed in consideration of translucency.

### Third Modified Example

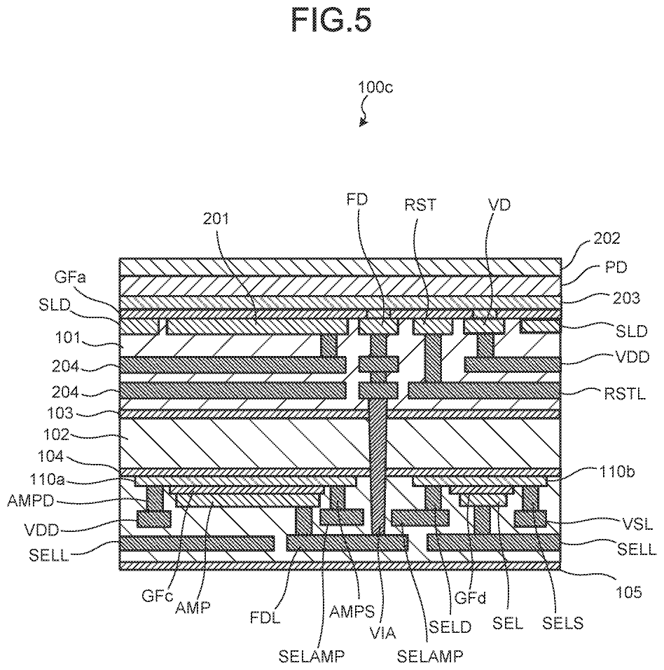

As illustrated in FIG. 5, in a solid-state imaging element 100c according to a third modified example, the internal structure of the second insulating layer 102 is different from that of the solid-state imaging element 100 illustrated in FIG. 2, and the structure above the second insulating layer 102 is the same as that of the solid-state imaging element 100 illustrated in FIG. 2.

As illustrated in FIG. 5, the internal structure of the second insulating layer 102 in the solid-state imaging element 100c is substantially similar to the structure obtained by inverting the top and bottom of the internal structure of the second insulating layer 102 illustrated in FIG. 2. However, in the solid-state imaging element 100c, the amplification transistor and the selection transistor are separated into the left and right by the through electrode VIA.

Therefore, the amplification gate AMP is provided on the one main surface (here, lower surface) of the transparent semiconductor layer 110a via a gate insulating film GFc. In addition, the selection gate SEL is provided on one main surface (here, lower surface) of the transparent semiconductor layer 110b via a gate insulating film GFd.

In addition, the source electrode AMPS of the amplification transistor and the drain electrode SELD of the selection transistor SELL are connected by a connection wiring SELLAMP. In addition, the through electrode VIA and the amplification gate AMP are connected by a connection wiring FDL.

As described above, in the solid-state imaging element 100c, similarly to the solid-state imaging element 100 illustrated in FIG. 2, the reset gate RST is provided in the first insulating layer 101, and the amplification transistor and the selection transistor are provided in the second insulating layer 102. As a result, similarly to the solid-state imaging element 100 illustrated in FIG. 2, the solid-state imaging element 100c can improve the light receiving sensitivity, reduce noise of the amplification transistor, and increase the speed.

### Fourth Modified Example

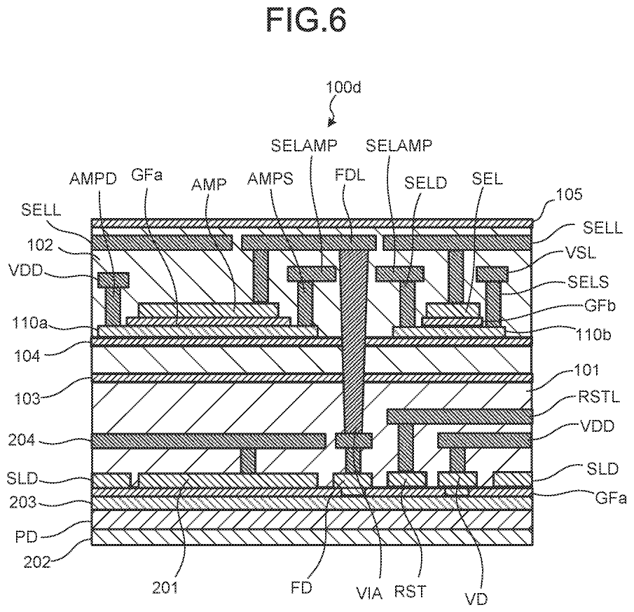

As illustrated in FIG. 6, a solid-state imaging element 100d according to a fourth modified example is substantially similar to a structure obtained by inverting the top and bottom of the stacked structure illustrated in FIG. 5. For this reason, similarly to the solid-state imaging element 100c illustrated in FIG. 5, the solid-state imaging element 100d can improve the light receiving sensitivity, reduce noise of the amplification transistor, and increase the speed.

Furthermore, in the solid-state imaging element 100d, the second electrode 202 in the lowermost layer is stacked on the second electrode 202 of the light receiving unit G (see FIG. 2) that is provided below via the insulating film and detects green light, which means that the second electrode 202 is stacked on the photoelectric conversion layer of the light receiving unit G.

As a result, in the solid-state imaging element 100d, a distance between the photoelectric conversion film PD of the light receiving unit B and the photoelectric conversion film PD of the light receiving unit G becomes shorter than that in the solid-state imaging element 100 illustrated in FIG. 2. Accordingly, the solid-state imaging element 100d can easily position a condensing point of the incident light.

### Fifth Modified Example

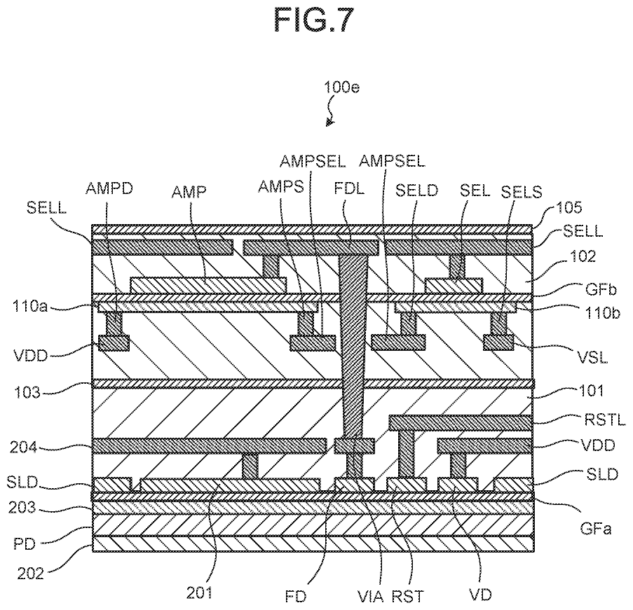

As illustrated in FIG. 7, a solid-state imaging element 100e according to a fifth modified example is substantially similar to a structure obtained by inverting the top and bottom of the stacked structure illustrated in FIG. 4. For this reason, similarly to the solid-state imaging element 100c illustrated in FIG. 4, the solid-state imaging element 100e can improve the light receiving sensitivity, reduce noise of the amplification transistor, and increase the speed. Still more, the solid-state imaging element 100e can appropriately route the selection signal line SELL, the vertical signal line VSL, the power supply line VDD, and the connection wirings SELAMP and FDL in consideration of translucency.

Furthermore, in the solid-state imaging element 100e, the distance between the photoelectric conversion film PD of the light receiving unit B and the photoelectric conversion film PD of the light receiving unit G is shortened, similarly to the solid-state imaging element 100d illustrated in FIG. 6. Accordingly, the solid-state imaging element 100e can easily position the condensing point of the incident light.

### Sixth Modified Example

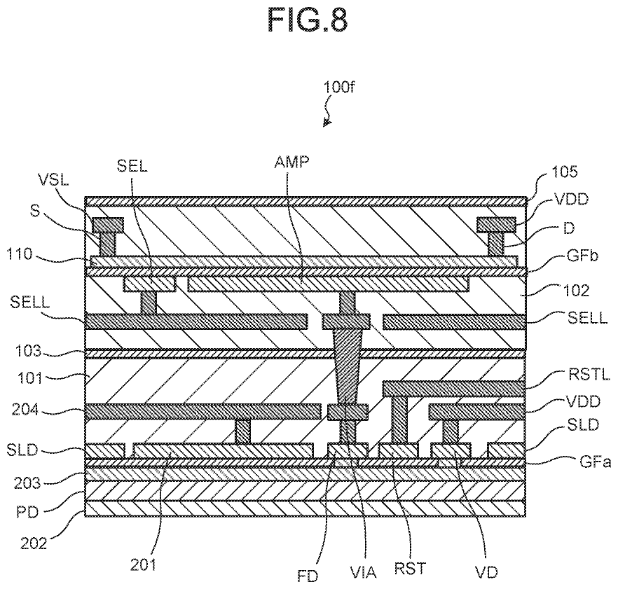

As illustrated in FIG. 8, a solid-state imaging element 100f according to a sixth modified example is substantially similar to a structure obtained by inverting the top and bottom of the stacked structure illustrated in FIG. 3. For this reason, similarly to the solid-state imaging element 100c illustrated in FIG. 3, the solid-state imaging element 100f can improve the light receiving sensitivity, reduce noise of the amplification transistor, and increase the speed.

Still more, the solid-state imaging element 100f can appropriately route the selection signal line SELL, the vertical signal line VSL, the power supply line VDD, and the connection wirings SELAMP and FDL in consideration of translucency.

Furthermore, in the solid-state imaging element 100f, the distance between the photoelectric conversion film PD of the light receiving unit B and the photoelectric conversion film PD of the light receiving unit G is shortened, similarly to the solid-state imaging element 100d illustrated in FIG. 6. Accordingly, the solid-state imaging element 100f can easily position the condensing point of the incident light.

### Seventh Modified Example

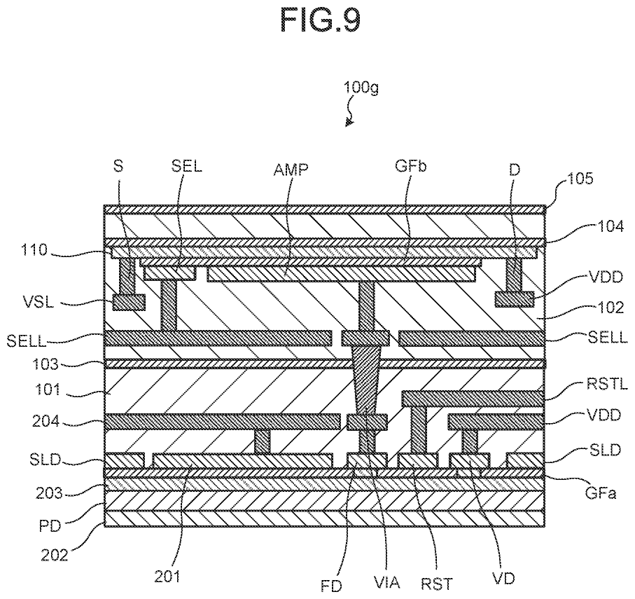

As illustrated in FIG. 9, a solid-state imaging element 100g according to a seventh modified example is substantially similar to a structure obtained by inverting the top and bottom of the light receiving unit B illustrated in FIG. 2. For this reason, similarly to the solid-state imaging element 100c illustrated in FIG. 2, the solid-state imaging element 100g can improve the light receiving sensitivity, reduce noise of the amplification transistor, and increase the speed.

Furthermore, in the solid-state imaging element 100g, the distance between the photoelectric conversion film PD of the light receiving unit B and the photoelectric conversion film PD of the light receiving unit G is shortened, similarly to the solid-state imaging element 100d illustrated in FIG. 6. Accordingly, the solid-state imaging element 100g can easily position the condensing point of the incident light.

### Eighth Modified Example

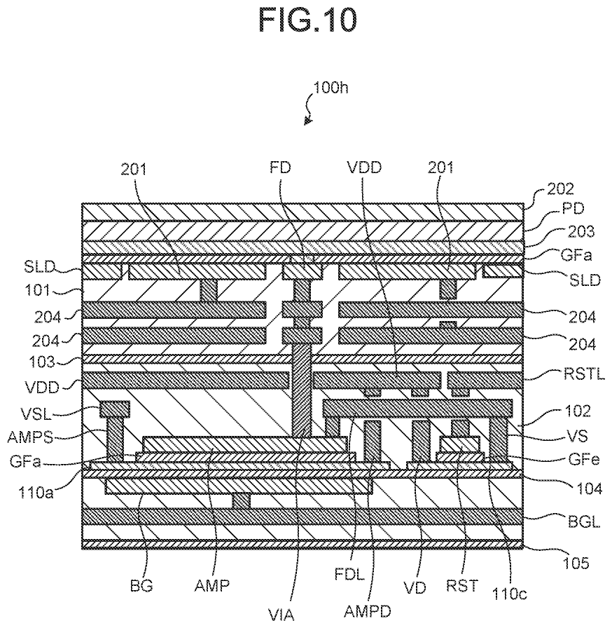

As illustrated in FIG. 10, in a solid-state imaging element 100h according to an eighth modified example, the transparent semiconductor layer 110a is provided on the intermediate insulating film 104 provided in the second insulating layer 102, and the amplification gate AMP is provided on the transparent semiconductor layer 110a via the gate insulating film GFa.

The amplification gate AMP is connected to the transfer electrode FD via the through electrode VIA. The source AMPS of the amplification transistor is connected to the vertical signal line VSL. The drain AMPD of the amplification transistor is connected to the power supply line VDD.

Furthermore, in the amplification transistor, a back gate BG is provided under the amplification gate AMP via the gate insulating film GFa, the transparent semiconductor layer 110a, and the intermediate insulating film 104. The back gate BG is provided so as to at least partially overlap the amplification gate AMP in a plan view. The back gate G is connected to a back gate line BGL on the lower surface.

The amplification transistor according to the eighth modified example can perform threshold control and ON and OFF switching control by controlling a voltage applied to the back gate BG via the back gate line BGL. As a result, the solid-state imaging element 100h can output the photoelectrically converted signal charge to the vertical signal line VSL by turning on the amplification transistor, and can stop the output of the signal charge to the vertical signal line VSL by turning off the amplification transistor.

As described above, the solid-state imaging element 100h can switch between the output of the signal charge to the vertical signal line VSL and the output stop thereof by controlling the voltage applied to the back gate BG of the amplification transistor. Accordingly, the selection transistor becomes unnecessary.

As a result, in the solid-state imaging element 100h, for example, the reset transistor can be provided in the second insulating layer 102 instead of the selection transistor illustrated in FIG. 2. Specifically, in the solid-state imaging element 100h, a transparent semiconductor layer 110c is provided on the intermediate insulating film 104 provided in the second insulating layer 102, and the reset gate RST is provided on the transparent semiconductor layer 110c via a gate insulating film GFe.

The reset gate RST is connected to a reset line RSTL. The discharge electrode VD serving as the drain electrode of the reset transistor is connected to the power supply line VDD. A source electrode VS of the reset transistor is connected to the amplification gate AMP via the connection wiring FDL.

As described above, in the solid-state imaging element 100h, since the reset transistor is provided in the second insulating layer 102, another first electrode 201 can be provided, for example, on the uppermost layer of the first insulating layer 101 where the reset gate RST and the discharge electrode VD is provided in FIG. 2.

The two first electrodes 201 provided on the uppermost layer of the first insulating layer 101 share one transfer electrode FD. Accordingly, the solid-state imaging element 100h can have a one-pixel two-cell configuration, and thus can capture an image with higher definition.

[4. Multilayer Wiring Configuration]

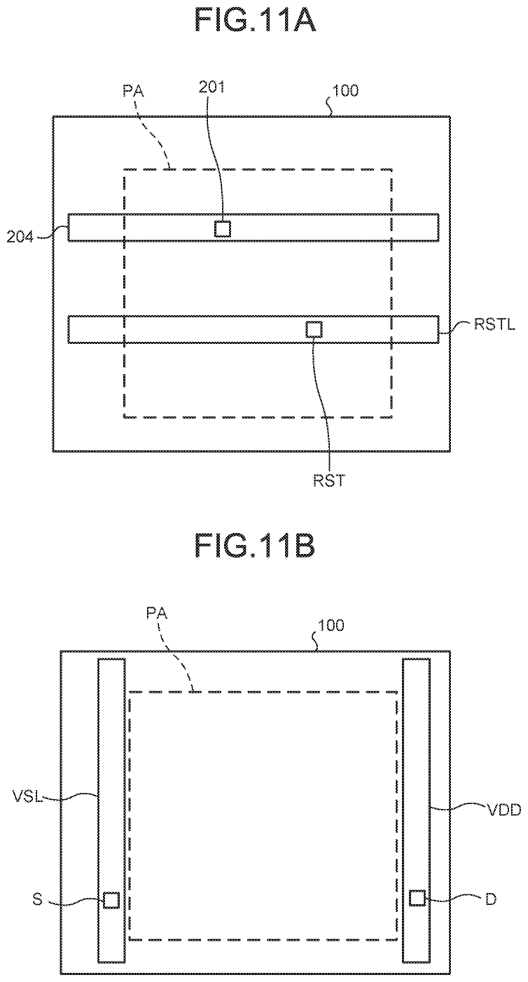

Next, multilayer wiring of the solid-state imaging element 100 will be described. FIG. 11A and FIG. 11B are explanatory diagrams of the multilayer wiring according to the present disclosure. As illustrated in FIG. 11A, in the solid-state imaging element 100, for example, wiring that crosses a light receiving region PA of the photoelectric conversion film PD in a plan view, such as the charge storage wiring 204 and the reset line RST, is configured with a transparent wiring formed of a transparent conductive film. As a result, the solid-state imaging element 100 can improve the light receiving sensitivity by preventing the incident light from being blocked by the wiring crossing the light receiving region PA of the photoelectric conversion film PD.

Furthermore, as illustrated in FIG. 11B, for example, in the solid-state imaging element 100, wiring that requires low resistance, such as the power supply line VDD and the vertical signal line VSL, is provided around the light receiving region PA of the photoelectric conversion film PD in a plan view, and is configured with metal wiring. As a result, the solid-state imaging element 100 can minimize a power loss caused by the power supply line VDD and increase a transmission speed of the pixel signal by the vertical signal line VSL without lowering the light receiving sensitivity.

[5. Application to Electronic Apparatus]

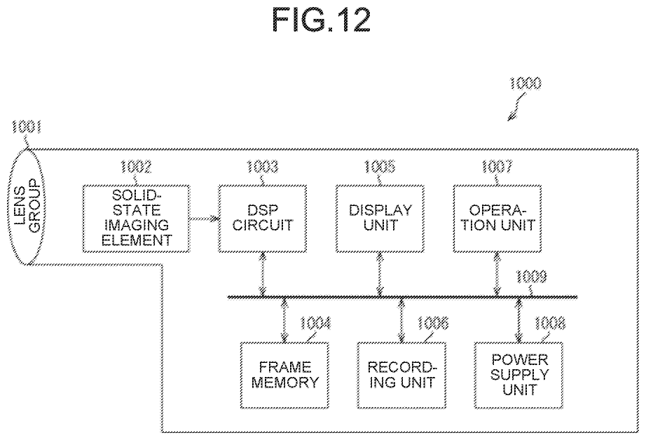

Technology according to the present disclosure (present technology) can be applied to various products. The technology according to the present disclosure (present technology) may be applied to, for example, an imaging apparatus as an electronic apparatus. FIG. 12 is a block diagram illustrating a configuration example of an embodiment of the imaging apparatus as the electronic apparatus to which the present disclosure is applied.

An imaging apparatus 1000 in FIG. 12 is a video camera, a digital still camera, or the like. The imaging apparatus 1000 includes a lens group 1001, a solid-state imaging element 1002, a DSP circuit 1003, a frame memory 1004, a display unit 1005, a recording unit 1006, an operation unit 1007, and a power supply unit 1008.

The DSP circuit 1003, the frame memory 1004, the display unit 1005, the recording unit 1006, the operation unit 1007, and the power supply unit 1008 are connected to each other via a bus line 1009. The lens group 1001 captures incident light (image light) from a subject and forms an image on an imaging surface of the solid-state imaging element 1002.

The solid-state imaging elements 100 to 100h described with reference to FIG. 2 to FIG. 10 are applied to the solid-state imaging element 1002. The solid-state imaging element 1002 converts an amount of incident light imaged on the imaging surface by the lens group 1001 into an electric signal in pixel units, and supplies the electric signal to the DSP circuit 1003 as a pixel signal.

The DSP circuit 1003 performs predetermined image processing on the pixel signal supplied from the solid-state imaging element 1002, and supplies an image signal after the image processing to the frame memory 1004 in frame units to cause the frame memory 1004 temporarily to store the image signal.

The display unit 1005 includes, for example, a panel type display device such as a liquid crystal panel or an organic electro luminescence (EL) panel, and displays an image based on the pixel signal in frame units temporarily stored in the frame memory 1004.

The recording unit 1006 includes a digital versatile disk (DVD), a flash memory, and the like, and reads and records the pixel signal in frame units temporarily stored in the frame memory 1004. The operation unit 1007 generates operation commands for various functions of the imaging apparatus 1000 under operation by the user.

The power supply unit 1008 appropriately supplies power to the DSP circuit 1003, the frame memory 1004, the display unit 1005, the recording unit 1006, and the operation unit 1007. The electronic apparatus to which the present technology is applied may be any apparatus using an image sensor as an image capturing unit (photoelectric conversion unit), and examples thereof include a mobile terminal apparatus having an imaging function and a copying machine using the image sensor as an image reader, in addition to the imaging apparatus 1000.

[6. Application to Endoscopic Surgery System]

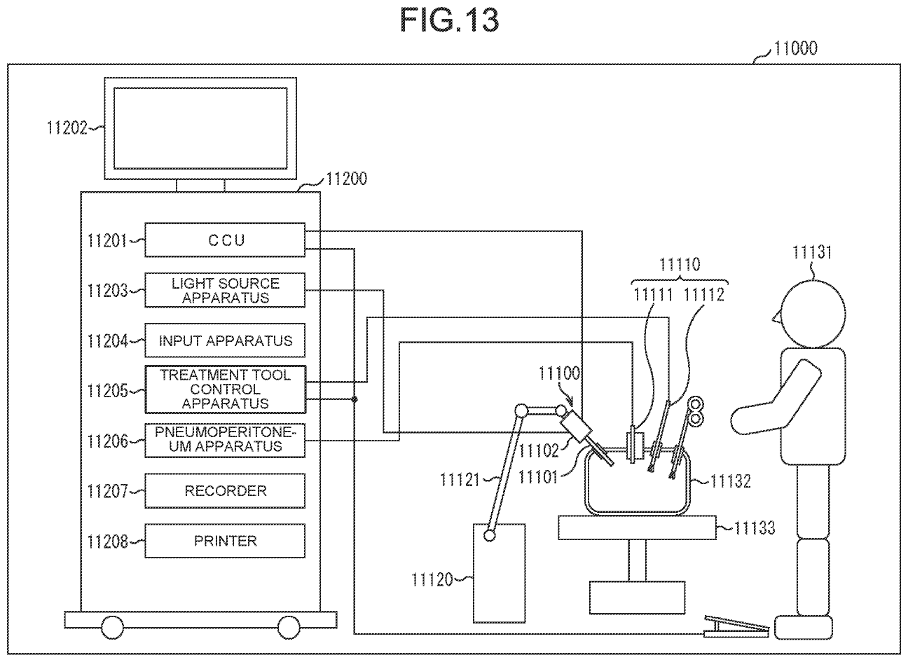

The technology according to the present disclosure (present technology) may also be applied to, for example, an endoscopic surgery system. FIG. 13 is a diagram illustrating a schematic configuration example of the endoscopic surgery system to which the technology according to the present disclosure (present technology) can be applied.

FIG. 13 illustrates a state in which an operator (doctor) 11131 is performing surgery on a patient 11132 on a patient bed 11133 using an endoscopic surgery system 11000. As illustrated, the endoscopic surgery system 11000 includes an endoscope 11100, other surgical tools 11110 such as a pneumoperitoneum tube 11111 and an energy treatment tool 11112, a support arm apparatus 11120 that supports the endoscope 11100, and a cart 11200 on which various apparatuses for endoscopic surgery are placed.

The endoscope 11100 includes a lens barrel 11101 whose region of a predetermined length from a distal end is inserted into a body cavity of the patient 11132, and a camera head 11102 connected to a base end of the lens barrel 11101. In an illustrated example, the endoscope 11100 configured as a so-called rigid scope having the rigid lens barrel 11101 is illustrated, but the endoscope 11100 may be configured as a so-called flexible scope having a flexible lens barrel.

An opening portion into which an objective lens is fitted is provided at the distal end of the lens barrel 11101. A light source apparatus 11203 is connected to the endoscope 11100. Light generated by the light source apparatus 11203 is guided to the distal end of the lens barrel by a light guide extending inside the lens barrel 11101, and is emitted toward an observation target in the body cavity of the patient 11132 via the objective lens. Note that the endoscope 11100 may be a forward-viewing endoscope, an oblique-viewing endoscope, or a side-viewing endoscope.

An optical system and an imaging element are provided inside the camera head 11102, and reflected light (observation light) from the observation target is condensed on the imaging element by the optical system. The observation light is photoelectrically converted by the imaging element, and an electric signal corresponding to the observation light, i.e., an image signal corresponding to an observation image, is generated. The image signal is transmitted to a camera control unit (CCU) 11201 as RAW data.

The CCU 11201 includes a central processing unit (CPU), a graphics processing unit (GPU), and the like, and integrally controls an operation of the endoscope 11100 and a display device 11202. Furthermore, the CCU 11201 receives the image signal from the camera head 11102, and performs various types of image processing for displaying an image based on the image signal, such as development processing (demosaic processing).

The display device 11202 displays the image based on the image signal subjected to the image processing by the CCU 11201 under the control of the CCU 11201.

The light source apparatus 11203 includes a light source such as a light emitting diode (LED), and supplies irradiation light for photographing a surgical site or the like to the endoscope 11100.

An input apparatus 11204 is an input interface for the endoscopic surgery system 11000. The user can input various types of information and instructions to the endoscopic surgery system 11000 via the input apparatus 11204. For example, the user inputs an instruction and the like to change imaging conditions (type of irradiation light, magnification, focal length, and the like) of the endoscope 11100.

A treatment tool control apparatus 11205 controls driving of the energy treatment tool 11112 for cauterization and incision of tissue, sealing of a blood vessel, or the like. A pneumoperitoneum apparatus 11206 feeds gas into the body cavity of the patient 11132 via the pneumoperitoneum tube 11111 in order to inflate the body cavity for the purpose of securing a visual field by the endoscope 11100 and securing a working space of the operator. A recorder 11207 is an apparatus capable of recording various types of information regarding surgery. A printer 11208 is an apparatus capable of printing various types of information regarding surgery in various formats such as text, image, or graph.

Note that the light source apparatus 11203 that supplies the endoscope 11100 with the irradiation light at the time of imaging the surgical site may include, for example, an LED, a laser light source, or a white light source configured by a combination thereof. In a case where the white light source is configured by combining RGB laser light sources, adjustment of a white balance of a captured image can be performed in the light source apparatus 11203 because an output intensity and an output timing of each color (each wavelength) can be accurately controlled. Furthermore, in this case, by irradiating the observation target with the laser light from each of the RGB laser light sources in a time division manner and controlling the driving of the imaging element of the camera head 11102 in synchronization with the irradiation timing, it is also possible to capture an image corresponding to each of RGB in a time division manner. According to this method, a color image can be obtained without providing a color filter in the imaging element.

Furthermore, the driving of the light source apparatus 11203 may be controlled so as to change the intensity of light to be output according to predetermined time. By controlling the driving of the imaging element of the camera head 11102 in synchronization with the timing of changing the light intensity to acquire images in a time division manner and synthesizing the images, it is possible to generate an image with a high dynamic range without so-called blocked-up shadows and blown-out highlights.

Furthermore, the light source apparatus 11203 may be configured to be able to supply light in a predetermined wavelength band corresponding to special light observation. In the special light observation, for example, so-called narrow band imaging is performed in which a predetermined tissue such as a blood vessel in a mucosal surface layer is imaged with high contrast by irradiating light in a narrower band than irradiation light (i.e., white light) for the normal observation by utilizing wavelength dependency of light absorption in a body tissue. Alternatively, in the special light observation, fluorescence observation for obtaining an image by fluorescence generated by irradiation with excitation light may be performed. In the fluorescence observation, for example, it is possible to irradiate the body tissue with the excitation light to observe fluorescence from the body tissue (autofluorescence observation), or to locally inject a reagent such as indocyanine green (ICG) into the body tissue and irradiate the body tissue with the excitation light corresponding to a fluorescence wavelength of the reagent to obtain a fluorescent image. The light source apparatus 11203 can be configured to be able to supply the narrow band light and/or the excitation light corresponding to these special light observations.

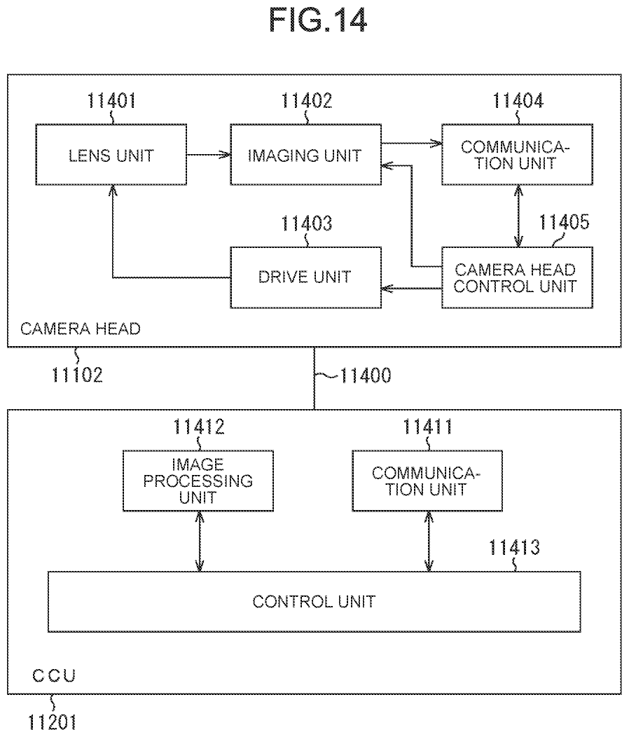

FIG. 14 is a block diagram illustrating an example of functional configurations of the camera head 11102 and the CCU 11201 illustrated in FIG. 13.

The camera head 11102 includes a lens unit 11401, an imaging unit 11402, a drive unit 11403, a communication unit 11404, and a camera head control unit 11405. The CCU 11201 includes a communication unit 11411, an image processing unit 11412, and a control unit 11413. The camera head 11102 and the CCU 11201 are communicably connected to each other by a transmission cable 11400.

The lens unit 11401 is an optical system provided at a connection portion with the lens barrel 11101. The observation light taken in from the distal end of the lens barrel 11101 is guided to the camera head 11102 and enters the lens unit 11401. The lens unit 11401 is configured by combining a plurality of lenses including a zoom lens and a focus lens.

The imaging unit 11402 includes an imaging element. The number of imaging elements configuring the imaging unit 11402 may be one (so-called single-plate type) or a plural (so-called multi-plate type). In a case where the imaging unit 11402 is configured as the multi-plate type, image signals corresponding to RGB, for example, are generated by respective imaging elements, and a color image may be obtained by combining the image signals.

Alternatively, the imaging unit 11402 may include a pair of imaging elements for acquiring right-eye and left-eye image signals corresponding to three-dimensional (3D) display. By performing the 3D display, the operator 11131 can more accurately grasp a depth of a living tissue in the surgical site. Note that, in a case where the imaging unit 11402 is configured as the multi-plate type, a plurality of lens units 11401 may be provided corresponding to the respective imaging elements.

Furthermore, the imaging unit 11402 is not necessarily provided in the camera head 11102. For example, the imaging unit 11402 may be provided immediately after the objective lens inside the lens barrel 11101.

The drive unit 11403 includes an actuator, and moves the zoom lens and the focus lens of the lens unit 11401 for a predetermined distance along an optical axis under the control of the camera head control unit 11405. As a result, a magnification and a focus of an image captured by the imaging unit 11402 can be appropriately adjusted.

The communication unit 11404 includes a communication device for transmitting and receiving various types of information to and from the CCU 11201. The communication unit 11404 transmits the image signal obtained from the imaging unit 11402 as the RAW data to the CCU 11201 via the transmission cable 11400.

Furthermore, the communication unit 11404 receives a control signal for controlling the driving of the camera head 11102 from the CCU 11201, and supplies the control signal to the camera head control unit 11405. The control signal includes, for example, information regarding imaging conditions such as information for specifying a frame rate of a captured image, information for specifying an exposure at the time of imaging, and/or information for specifying a magnification and a focus of the captured image.

Note that the imaging conditions such as the frame rate, the exposure, the magnification, and the focus may be appropriately specified by the user, or may be automatically set by the control unit 11413 of the CCU 11201 according to the image signal acquired. In the latter case, a so-called auto exposure (AE) function, an auto focus (AF) function, and an auto white balance (AWB) function are installed in the endoscope 11100.

The camera head control unit 11405 controls the driving of the camera head 11102 based on the control signal from the CCU 11201 received via the communication unit 11404.

The communication unit 11411 includes a communication device for transmitting and receiving various types of information to and from the camera head 11102. The communication unit 11411 receives the image signal transmitted from the camera head 11102 via the transmission cable 11400.

Furthermore, the communication unit 11411 transmits a control signal for controlling the driving of the camera head 11102 to the camera head 11102. The image signal and the control signal can be transmitted by electric communication, optical communication, or the like.

The image processing unit 11412 performs various types of image processing on the image signal that is the RAW data transmitted from the camera head 11102.

The control unit 11413 performs various types of control related to imaging of the surgical site or the like by the endoscope 11100 and display of the captured image obtained by imaging the surgical site or the like. For example, the control unit 11413 generates a control signal for controlling the driving of the camera head 11102.

Furthermore, the control unit 11413 causes the display device 11202 to display the captured image of the surgical site or the like based on the image signal subjected to the image processing by the image processing unit 11412. In this case, the control unit 11413 may recognize various objects in the captured image using various image recognition technologies. For example, the control unit 11413 can recognize a surgical tool such as forceps, a specific body part, bleeding, and mist at the time of using the energy treatment tool 11112 by detecting a shape of the edge, color, and the like of the object included in the captured image. When displaying the captured image on the display device 11202, the control unit 11413 may superimpose and display various types of surgery support information on the image of the surgical site by using a recognition result. Since the surgery support information is superimposed, displayed, and presented to the operator 11131, a burden on the operator 11131 can be reduced and the operator 11131 can reliably proceed with the surgery.

The transmission cable 11400 connecting the camera head 11102 and the CCU 11201 is an electric signal cable corresponding to electric signal communication, an optical fiber corresponding to optical communication, or a composite cable thereof.

In the illustrated example, communication is performed by wire using the transmission cable 11400, but communication between the camera head 11102 and the CCU 11201 may be performed wirelessly.

An example of the endoscopic surgery system to which the technology according to the present disclosure can be applied has been described above. The technology according to the present disclosure can be applied to, for example, the endoscope 11100, the imaging unit 11402 of the camera head 11102, and the like in the above-described configurations. Specifically, the solid-state imaging device 1 in FIG. 1 can be applied to the imaging unit 10402. By applying the technology according to the present disclosure to the imaging unit 10402, it is possible to obtain a clearer image of the surgical site by further improving the sensitivity and reducing noise of each solid-state imaging element 100, so that the operator can reliably confirm the surgical site.

Note that the endoscopic surgery system has been described as an example, and the technology according to the present disclosure may also be applied to, for example, a microscopic surgery system.

[7. Application to Mobile Body]

Furthermore, the technology according to the present disclosure (present technology) may be realized as, for example, an apparatus mounted on any type of mobile body such as an automobile, an electric vehicle, a hybrid electric vehicle, a motorcycle, a bicycle, a personal mobility, an airplane, a drone, a ship, and a robot.

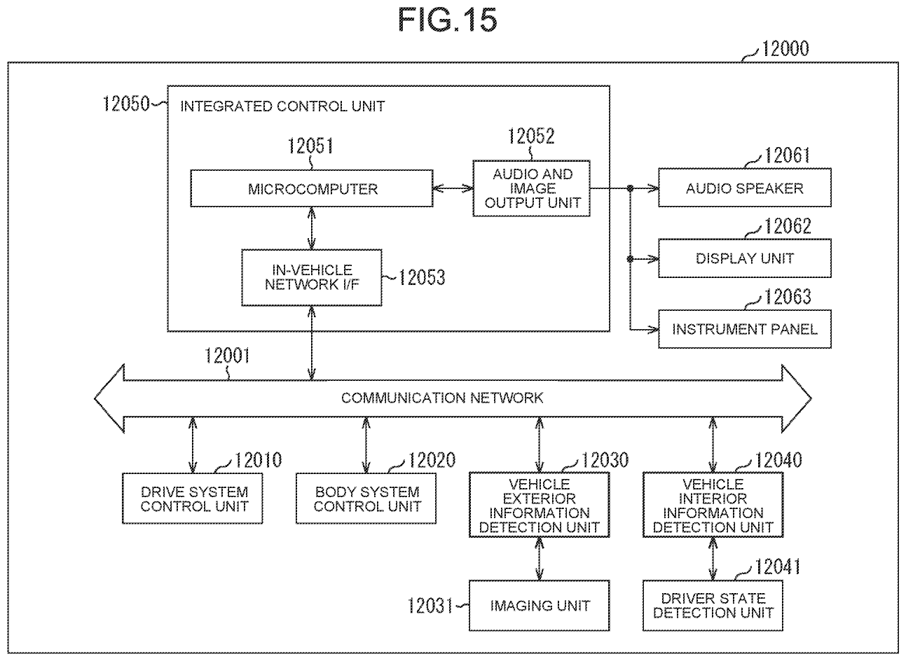

FIG. 15 is a block diagram illustrating a schematic configuration example of a vehicle control system as an example of a mobile body control system to which the technology according to the present disclosure can be applied.

A vehicle control system 12000 includes a plurality of electronic control units connected via a communication network 12001. In the example illustrated in FIG. 15, the vehicle control system 12000 includes a drive system control unit 12010, a body system control unit 12020, a vehicle exterior information detection unit 12030, a vehicle interior information detection unit 12040, and an integrated control unit 12050. Furthermore, as a functional configuration of the integrated control unit 12050, a microcomputer 12051, an audio and image output unit 12052, and an in-vehicle network interface (I/F) 12053 are illustrated.

The drive system control unit 12010 controls the operation of devices related to the drive system of the vehicle according to various programs. For example, the drive system control unit 12010 functions as a control device of a driving force generation device for generating a driving force of a vehicle such as an internal combustion engine or a driving motor, a driving force transmission mechanism for transmitting the driving force to wheels, a steering mechanism for adjusting a steering angle of the vehicle, a braking device for generating a braking force of the vehicle, and the like.

The body system control unit 12020 controls operations of various devices mounted on a vehicle body according to various programs. For example, the body system control unit 12020 functions as a control device of a keyless entry system, a smart key system, a power window device, or various lamps including a head lamp, a back lamp, a brake lamp, a blinker, a fog lamp, and the like. In this case, radio waves transmitted from a portable device that substitutes for a key or signals of various switches can be input to the body system control unit 12020. The body system control unit 12020 receives input of these radio waves or signals, and controls a door lock device, a power window device, a lamp, and the like of the vehicle.

The vehicle exterior information detection unit 12030 detects information outside the vehicle on which the vehicle control system 12000 is mounted. For example, an imaging unit 12031 is connected to the vehicle exterior information detection unit 12030. The vehicle exterior information detection unit 12030 causes the imaging unit 12031 to capture an image of the outside of the vehicle, and receives the captured image. The vehicle exterior information detection unit 12030 may perform an object detection process or a distance detection process of a person, a vehicle, an obstacle, a sign, a character on a road surface, or the like based on the received image.

The imaging unit 12031 is an optical sensor that receives light and outputs an electric signal corresponding to an amount of received light. The imaging unit 12031 can output the electric signal as an image or can output the electric signal as distance measurement information. Furthermore, the light received by the imaging unit 12031 may be visible light or invisible light such as infrared rays.

The vehicle interior information detection unit 12040 detects information inside the vehicle. For example, a driver state detection unit 12041 that detects a state of a driver is connected to the vehicle interior information detection unit 12040. The driver state detection unit 12041 includes, for example, a camera that images the driver, and the vehicle interior information detection unit 12040 may calculate a degree of fatigue or a degree of concentration of the driver or may determine whether or not the driver is dozing off based on the detection information input from the driver state detection unit 12041.

The microcomputer 12051 can calculate a target control value of the driving force generation device, the steering mechanism, or the braking device based on the information inside and outside the vehicle acquired by the vehicle exterior information detection unit 12030 or the vehicle interior information detection unit 12040, and output a control command to the drive system control unit 12010. For example, the microcomputer 12051 can perform cooperative control for the purpose of implementing functions of an advanced driver assistance system (ADAS) including collision avoidance or impact mitigation of the vehicle, following travel based on an inter-vehicle distance, vehicle speed maintenance travel, vehicle collision warning, vehicle lane departure warning, or the like.

Furthermore, the microcomputer 12051 controls the driving force generation device, the steering mechanism, the braking device, or the like based on the information around the vehicle acquired by the vehicle exterior information detection unit 12030 or the vehicle interior information detection unit 12040, thereby performing cooperative control for the purpose of automatic driving or the like in which the vehicle autonomously travels without depending on the operation by the driver.

Furthermore, the microcomputer 12051 can output a control command to the body system control unit 12020 based on the vehicle exterior information acquired by the vehicle exterior information detection unit 12030. For example, the microcomputer 12051 can perform cooperative control for the purpose of preventing glare, such as switching from a high beam to a low beam, by controlling the head lamp according to the position of a preceding vehicle or an oncoming vehicle detected by the vehicle exterior information detection unit 12030.

The audio and image output unit 12052 transmits an output signal of at least one of sound or an image to an output device capable of visually or audibly notifying an occupant of the vehicle or the outside of the vehicle of information. In the example in FIG. 15, an audio speaker 12061, a display unit 12062, and an instrument panel 12063 are illustrated as the output device. The display unit 12062 may include, for example, at least one of an on-board display and a head-up display.

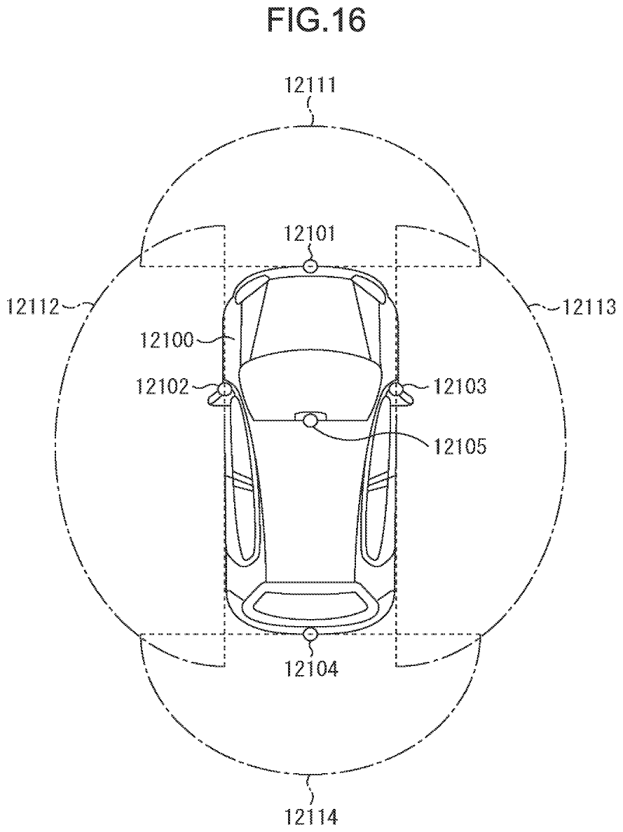

FIG. 16 is a diagram illustrating an example of an installation position of the imaging unit 12031.

In FIG. 16, a vehicle 12100 includes imaging units 12101, 12102, 12103, 12104, and 12105 as the imaging unit 12031.

The imaging units 12101, 12102, 12103, 12104, and 12105 are provided, for example, at positions such as a front nose, a side mirror, a rear bumper, a back door, and an upper portion of a windshield in a vehicle interior of the vehicle 12100. The imaging unit 12101 provided at the front nose and the imaging unit 12105 provided at the upper portion of the windshield in the vehicle interior mainly acquire images in front of the vehicle 12100. The imaging units 12102 and 12103 provided at the side mirrors mainly acquire images of the sides of the vehicle 12100. The imaging unit 12104 provided on the rear bumper or the back door mainly acquires an image behind the vehicle 12100. The front images acquired by the imaging units 12101 and 12105 are mainly used for detecting a preceding vehicle, a pedestrian, an obstacle, a traffic light, a traffic sign, a lane, or the like.

Note that FIG. 16 illustrates an example of imaging ranges of the imaging units 12101 to 12104. An imaging range 12111 indicates an imaging range of the imaging unit 12101 provided at the front nose, imaging ranges 12112 and 12113 indicate imaging ranges of the imaging units 12102 and 12103 provided at the side mirrors, respectively, and an imaging range 12114 indicates an imaging range of the imaging unit 12104 provided at the rear bumper or the back door. For example, by superimposing image data captured by the imaging units 12101 to 12104, an overhead view image of the vehicle 12100 viewed from above is obtained.

At least one of the imaging units 12101 to 12104 may have a function of acquiring distance information. For example, at least one of the imaging units 12101 to 12104 may be a stereo camera including a plurality of imaging elements, or may be an imaging element having pixels for phase difference detection.

For example, the microcomputer 12051 obtains a distance to each three-dimensional object in the imaging ranges 12111 to 12114 and a temporal change of the distance (relative speed with respect to the vehicle 12100) based on the distance information obtained from the imaging units 12101 to 12104, thereby extracting, as a preceding vehicle, a three-dimensional object traveling at a predetermined speed (e.g., 0 km/h or more) in substantially the same direction as the vehicle 12100, in particular, the closest three-dimensional object on a traveling path of the vehicle 12100. Furthermore, the microcomputer 12051 can set in advance an inter-vehicle distance to be secured with respect to the preceding vehicle, and can perform automatic brake control (including follow-up stop control), automatic acceleration control (including follow-up start control), and the like. As described above, it is possible to perform cooperative control for the purpose of automatic driving or the like in which the vehicle autonomously travels without depending on the operation by the driver.

For example, based on the distance information obtained from the imaging units 12101 to 12104, the microcomputer 12051 can classify three-dimensional object data regarding three-dimensional objects into two-wheeled vehicles, ordinary vehicles, large vehicles, pedestrians, and other three-dimensional objects such as utility poles, extract the three-dimensional object data, and use the three-dimensional object data for automatic avoidance of obstacles. For example, the microcomputer 12051 identifies obstacles around the vehicle 12100 as obstacles that can be visually recognized by the driver of the vehicle 12100 and obstacles that are difficult to visually recognize. Then, the microcomputer 12051 determines a collision risk indicating a risk of collision with each obstacle, and when the collision risk is a set value or more and there is a possibility of collision, the microcomputer 12051 can perform driving assistance for collision avoidance by outputting an alarm to the driver via the audio speaker 12061 or the display unit 12062 or performing forced deceleration or avoidance steering via the drive system control unit 12010.

At least one of the imaging units 12101 to 12104 may be an infrared camera that detects infrared rays. For example, the microcomputer 12051 can recognize a pedestrian by determining whether or not the pedestrian is present in the captured images of the imaging units 12101 to 12104. Such pedestrian recognition is performed by, for example, a procedure of extracting feature points in the captured images of the imaging units 12101 to 12104 as infrared cameras, and a procedure of performing pattern matching processing on a series of feature points indicating an outline of an object to determine whether or not the object is the pedestrian. When the microcomputer 12051 determines that the pedestrian is present in the captured images of the imaging units 12101 to 12104 and recognizes the pedestrian, the audio and image output unit 12052 controls the display unit 12062 to superimpose and display a square contour line for emphasis on the recognized pedestrian. Furthermore, the audio and image output unit 12052 may control the display unit 12062 to display an icon or the like indicating a pedestrian at a desired position.

An example of the vehicle control system to which the technology according to the present disclosure can be applied has been described above. The technology according to the present disclosure can be applied to, for example, the imaging unit 12031 and the like in the configuration described above. Specifically, for example, the solid-state imaging device 1 in FIG. 1 can be applied to the imaging unit 12031. By applying the technology according to the present disclosure to the imaging unit 12031, it is possible to obtain a more easily viewable captured image by further improving the sensitivity and reducing noise of each solid-state imaging element 100. Accordingly, it is possible to reduce driver's fatigue.

[8. Effects]

The solid-state imaging element 100 includes the photoelectric conversion layer, the first insulating layer 101, and the second insulating layer 102. The photoelectric conversion layer includes the insulating film Gfa, the charge storage layer 203, and the photoelectric conversion film PD stacked between the first electrode 201 and the second electrode 202. The first insulating layer 101 is provided with gates of some pixel transistors in which the charge storage layer serves as the source, the drain, and the channel among the plurality of pixel transistors that processes signal charges photoelectrically converted by the photoelectric conversion film PD. The second insulating layer 102 is provided with a pixel transistor other than the some pixel transistors among the plurality of pixel transistors. As a result, the solid-state imaging element 100 can improve the light receiving sensitivity by expanding the area of the first electrode 201.

Furthermore, the first insulating layer 101 is provided with the reset gate RST of the reset transistor that resets the signal charge. The second insulating layer 102 is provided with the amplification transistor that amplifies the signal charge. Therefore, the solid-state imaging element 100 can reduce noise superimposed on the pixel signal and increase the operation speed of the amplification transistor by expanding the area of the amplification gate AMP.

Furthermore, the second insulating layer 102 is provided with the selection transistor that selects the imaging pixel from which the signal charge is read. As a result, the solid-state imaging element 100 can expand the area of the first electrode 201 by effectively utilizing the first insulating layer 101.

The pixel transistor provided in the second insulating layer 102 includes the transparent semiconductor layer 110, the gate electrode provided on one main surface of the transparent semiconductor layer 110 via the gate insulating film GFb, and the source electrode and the drain electrode connected to one main surface of the transparent semiconductor layer 110. Also with such a configuration, the solid-state imaging element 100 can improve light receiving sensitivity, reduce noise, and increase the operation speed.

The pixel transistor provided in the second insulating layer 102 includes the transparent semiconductor layer 110, the gate electrode provided on one main surface of the transparent semiconductor layer 110 via the gate insulating film GFb, and the source electrode and the drain electrode connected to the other main surface of the transparent semiconductor layer 110. As a result, in the solid-state imaging element 100, routing flexibility of the wiring connected to the source electrode and the drain electrode is improved.

Still more, one main surface of the transparent semiconductor layer 110 faces the first insulating layer 101. Also with such a configuration, the solid-state imaging element 100 can improve light receiving sensitivity, reduce noise, and increase the operation speed.

The other main surface of the transparent semiconductor layer 110 faces the first insulating layer 101. Also with such a configuration, the solid-state imaging element 100 can improve light receiving sensitivity, reduce noise, and increase the operation speed.

In addition, the second insulating layer 102 is stacked on another photoelectric conversion layer that photoelectrically converts light of a color different from the light photoelectrically converted by the photoelectric conversion layer. As a result, the solid-state imaging element 100 can detect light of a plurality of types of colors with one pixel.

In addition, the photoelectric conversion layer is stacked on another photoelectric conversion layer that photoelectrically converts light of a color different from light to be photoelectrically converted by the photoelectric conversion layer. As a result, the solid-state imaging element 100 can easily position the condensing point of the incident light.

In addition, the wiring that crosses the light receiving region PA of the photoelectric conversion layer PD in a plan view is configured with the transparent wiring. As a result, the solid-state imaging element 100 can improve the light receiving sensitivity by preventing the incident light from being blocked by the wiring crossing the light receiving region PA of the photoelectric conversion film PD.

In addition, the power supply line VDD and the vertical signal line VSL from which the signal charges are read are provided around the light receiving region of the photoelectric conversion layer in a plan view, and are formed of the metal wiring. As a result, the solid-state imaging element can minimize the power loss caused by the power supply line VDD and increase the transmission speed of the pixel signal by the vertical signal line VSL without lowering the light receiving sensitivity.

In addition, the amplification gate AMP of the amplification transistor partially overlaps the first electrode 201 in a plan view. As a result, the solid-state imaging element 100 can further improve the light receiving sensitivity, further reduce the noise of the amplification transistor, and increase the operation speed.

The second insulating layer 102 is provided with the amplification transistor that amplifies the signal charge. The amplification transistor includes the back gate BG at least partially overlapping the amplification gate AMP via the gate insulating film GFa and the transparent semiconductor layer 110a in a plan view. As a result, the solid-state imaging element 100h can control switching between ON and OFF of the amplification transistor by controlling the voltage applied to the back gate BG, so that the selection transistor becomes unnecessary.

Note that the effects described in the present specification are merely examples and not limited, and other effects may be provided.

The present technology can also have the following configurations.

(1)

A solid-state imaging element including: a photoelectric conversion layer including an insulating film, a charge storage layer, and a photoelectric conversion film stacked between a first electrode and a second electrode;

a first insulating layer provided with gates of some pixel transistors among a plurality of pixel transistors that processes a signal charge photoelectrically converted by the photoelectric conversion film, the charge storage layer serving as a source, a drain, and a channel of the some pixel transistors; and

a second insulating layer provided with a pixel transistor among the plurality of pixel transistors, the pixel transistor being other than the some pixel transistors.

(2)

The solid-state imaging element according to (1), wherein

the first insulating layer is

provided with a gate of a reset transistor that resets the signal charge, and

the second insulating layer is

provided with an amplification transistor that amplifies the signal charge.

(3)

The solid-state imaging element according to (2), wherein

the second insulating layer is

provided with a selection transistor that selects an imaging pixel from which the signal charge is read.

(4)

The solid-state imaging element according to any one of (1) to (3), wherein

the pixel transistor provided in the second insulating layer includes

a transparent semiconductor layer,

a gate electrode provided on one main surface of the transparent semiconductor layer via a gate insulating film, and

a source electrode and a drain electrode connected to the one main surface of the transparent semiconductor layer.

(5)

The solid-state imaging element according to any one of (1) to (3), wherein

the pixel transistor provided in the second insulating layer includes

a transparent semiconductor layer,

a gate electrode provided on one main surface of the transparent semiconductor layer via a gate insulating film, and

a source electrode and a drain electrode connected to another main surface of the transparent semiconductor layer.

(6)

The solid-state imaging element according to (4) or (5), wherein

the one main surface of the transparent semiconductor layer

faces the first insulating layer.

(7)

The solid-state imaging element according to (5), wherein

the other main surface of the transparent semiconductor layer

faces the first insulating layer.

(8)

The solid-state imaging element according to any one of (1) to (7), wherein

the second insulating layer is

stacked on another photoelectric conversion layer that photoelectrically converts light of a color different from light photoelectrically converted by the photoelectric conversion layer.

(9)

The solid-state imaging element according to any one of (1) to (7), wherein

the photoelectric conversion layer is

stacked on another photoelectric conversion layer that photoelectrically converts light of a color different from light photoelectrically converted by the photoelectric conversion layer.

(10)

The solid-state imaging element according to any one of (1) to (9), wherein

a wiring crossing a light receiving region of the photoelectric conversion layer in a plan view is configured with a transparent wiring.

(11)

The solid-state imaging element according to any one of (1) to (10), wherein

a power supply line and a vertical signal line from which the signal charge is read are

provided around a light receiving region of the photoelectric conversion layer in a plan view, and are configured with a metal wiring.

(12)

The solid-state imaging element according to (2), wherein

a gate of the amplification transistor

partially overlaps the first electrode in a plan view.

(13)

The solid-state imaging element according to (1), wherein

the second insulating layer is

provided with an amplification transistor that amplifies the signal charge, and

the amplification transistor includes

a back gate that at least partially overlaps a gate in a plan view via a gate insulating film and a transparent semiconductor layer.

### REFERENCE SIGNS LIST

1 SOLID-STATE IMAGING DEVICE
100 SOLID-STATE IMAGING ELEMENT
101 FIRST INSULATING LAYER
110 TRANSPARENT SEMICONDUCTOR LAYER
102 SECOND INSULATING LAYER
201 FIRST ELECTRODE
202 SECOND ELECTRODE
203 CHARGE STORAGE LAYER
GFa, GFb GATE INSULATING FILM
PD PHOTOELECTRIC CONVERSION FILM
AMP AMPLIFICATION GATE
RST RESET GATE
SEL SELECTION GATE

1. A solid-state imaging element comprising:
a photoelectric conversion layer including an insulating film, a charge storage layer, and a photoelectric conversion film stacked between a first electrode and a second electrode;
a first insulating layer provided with gates of some pixel transistors among a plurality of pixel transistors that processes a signal charge photoelectrically converted by the photoelectric conversion film, the charge storage layer serving as a source, a drain, and a channel of the some pixel transistors; and
a second insulating layer provided with a pixel transistor among the plurality of pixel transistors, the pixel transistor being other than the some pixel transistors.

2. The solid-state imaging element according to claim 1, wherein
the first insulating layer is provided with a gate of a reset transistor that resets the signal charge, and
the second insulating layer is
provided with an amplification transistor that amplifies the signal charge.

3. The solid-state imaging element according to claim 2, wherein
the second insulating layer is
provided with a selection transistor that selects an imaging pixel from which the signal charge is read.

4. The solid-state imaging element according to claim 1, wherein
the pixel transistor provided in the second insulating layer includes
a transparent semiconductor layer,
a gate electrode provided on one main surface of the transparent semiconductor layer via a gate insulating film, and
a source electrode and a drain electrode connected to the one main surface of the transparent semiconductor layer.

5. The solid-state imaging element according to claim 1, wherein
the pixel transistor provided in the second insulating layer includes
a transparent semiconductor layer,
a gate electrode provided on one main surface of the transparent semiconductor layer via a gate insulating film, and
a source electrode and a drain electrode connected to another main surface of the transparent semiconductor layer.

6. The solid-state imaging element according to claim 4, wherein
the one main surface of the transparent semiconductor layer
faces the first insulating layer.

7. The solid-state imaging element according to claim 5, wherein
the other main surface of the transparent semiconductor layer
faces the first insulating layer.

8. The solid-state imaging element according to claim 1, wherein
the second insulating layer is
stacked on another photoelectric conversion layer that photoelectrically converts light of a color different from light photoelectrically converted by the photoelectric conversion layer.

9. The solid-state imaging element according to claim 1, wherein
the photoelectric conversion layer is stacked on another photoelectric conversion layer that photoelectrically converts light of a color different from light photoelectrically converted by the photoelectric conversion layer.

10. The solid-state imaging element according to claim 1, wherein
a wiring crossing a light receiving region of the photoelectric conversion layer in a plan view is
configured with a transparent wiring.

11. The solid-state imaging element according to claim 1, wherein
a power supply line and a vertical signal line from which the signal charge is read are
provided around a light receiving region of the photoelectric conversion layer in a plan view, and are configured with a metal wiring.

12. The solid-state imaging element according to claim 2, wherein
a gate of the amplification transistor
partially overlaps the first electrode in a plan view.

13. The solid-state imaging element according to claim 1, wherein
the second insulating layer is provided with an amplification transistor that amplifies the signal charge, and
the amplification transistor includes
a back gate that at least partially overlaps a gate in a plan view via a gate insulating film and a transparent semiconductor layer.
